(19) United States
(12) Patent Application Publication
(10) Pub. No.: US 2016/0005738 A1
(43) Pub. Date: Jan. 7, 2016

(54) SEMICONDUCTOR DEVICE HAVING A FIN STRUCTURE AND METHOD OF MANUFACTURE THE SAME

(71) Applicant: Samsung Electronics Co., Ltd., Suwon-si (KR)

(72) Inventors: Bin LIU, Suwon-si (KR); Sung-min KIM, Incheon (KR)

(21) Appl. No.: 14/716,822

(22) Filed: May 19, 2015

(30) Foreign Application Priority Data
Jul. 7, 2014 (KR) 10-2014-0084619

(51) Int. Cl. H01L 27/092

(52) U.S. Cl. CPC H01L 27/0924

(57) ABSTRACT

A semiconductor device is provided. In some examples, the semiconductor device includes: a substrate, a fin structure disposed with the substrate, a source and a drain that are formed in the fin structure, a channel area disposed between the source and the drain, a gate dielectric layer disposed on the channel area, and a gate line disposed on the gate dielectric layer. The fin structure may include an anti-punch through layer, an upper fin structure disposed on the anti-punch through layer, the upper fin structure including a material having a lattice constant to receive a compressive strain. The fin structure may also include a lower fin structure disposed under the anti-punch through layer, and may comprise the same material as the substrate.

### CROSS-REFERENCE TO RELATED APPLICATIONS

This application claims the benefit of Korean Patent Application No. 10-2014-0084619, filed on Jul. 7, 2014, in the Korean Intellectual Property Office, the disclosure of which is incorporated herein in its entirety by reference.

### BACKGROUND

The inventive concept relates to a semiconductor device, which may be a semiconductor device including a field effect transistor (FET) having a fin structure, that is, a fin-type field effect transistor (FinFET).

With higher integration density and lower power consumption of semiconductor devices, the sizes of elements of such semiconductor devices continue to decrease. Accordingly, channel areas of transistors have been gradually reduced and thus a short channel effect may undesirably occur in the transistors. As the size of FinFETs decreases, the FinFET has difficulty in improving a current driving capability. In addition, as channel sizes of the FinFET become smaller, a short channel effect becomes an issue.

### SUMMARY

A semiconductor device according to disclosed examples may comprise a substrate; a and a fin structure protruding from an upper surface of the substrate. The fin structure may comprise a first and second source/drain regions; and a channel region disposed between the first and second source/drain regions. A gate dielectric layer may be disposed on the channel area and a gate line may be disposed on the gate dielectric layer. The fin structure may include an anti-punch through layer; an upper fin structure disposed on the anti-punch through layer, the upper fin structure comprising a material having a lattice constant that is higher than that of silicon; and a lower fin structure disposed under the anti-punch through layer, the lower fin structure comprising the same material as the substrate.

The anti-punch through layer may have a dopant concentration that is higher than that of the upper fin structure.

The anti-punch through layer may include at least one selected from a silicon layer or a silicon germanium layer.

The anti-punch through layer may include an epitaxial growth layer.

A thickness of the anti-punch through layer may be smaller than that of the upper fin structure.

The anti-punch through layer may include a multiple layers of different materials.

The source/drain regions may include dopants of a first type, and the channel area may include dopants of a second type.

The source/drain regions may be doped with p-type dopants.

The upper fin structure may include a silicon germanium epitaxial growth layer.

The source/drain regions may each may have an upper surface of which a level is higher than that of an upper surface of the channel area.

According to another aspect of the inventive concept, there is provided a semiconductor device including: a substrate; an n-type transistor area and a p-type transistor area, formed on the substrate; a first fin structure formed in the n-type transistor area; a second fin structure formed in the p-type transistor area; a gate dielectric layer disposed on the first and second fin structures; and a gate line disposed on the gate dielectric layer, wherein the second fin structure includes: an anti-punch through layer; a second upper fin structure disposed on the anti-punch through layer, the second upper fin structure comprising a material having a lattice constant that is higher than that of silicon; and a second lower fin structure disposed under the anti-punch through layer, the second lower fin structure including the same material as the substrate.

The first fin structure may include the same material as the substrate.

The second upper fin structure may include a silicon germanium epitaxial growth layer.

The n-type transistor area and the p-type transistor area each may have a mesa structure.

The anti-punch through layer may have a doping concentration that is higher than that of the second upper fin structure.

The second upper fin structure may include a material that is different from that of the anti-punch through layer.

According to another aspect of the inventive concept, there is provided a semiconductor device including: a substrate; a first fin structure disposed on the substrate; and a second fin structure disposed on the substrate, wherein the second fin structure includes: an anti-punch through layer; a second upper fin structure disposed on the anti-punch through layer, the second upper fin structure comprising a material having a lattice constant that is higher than that of silicon; and a second lower fin structure disposed under the anti-punch through layer, the second lower fin structure comprising the same material as the substrate.

The semiconductor device may further include an insulating structure between the first fin structure and the second fin structure.

A lattice constant of a material of the first fin structure may be the same as that of a material of the substrate.

An upper surface of the insulating structure may be positioned at the same level as a boundary between the ant-punch through layer and the second upper fin structure.

Methods of manufacturing a semiconductor device may comprise providing a fin with a semiconductor substrate, the fin including a lower portion, a middle portion with a dopant of a first type and an upper portion with the dopant of the first type, the middle portion being formed by epitaxially growing a first crystalline material on the lower portion, the upper portion being formed by epitaxially growing a second crystalline material on the middle portion, wherein the first crystalline material of the middle portion is doped with a doping concentration of x, x being a value higher than 0, and the second crystalline material is with a doping concentration of y, y being a value equal to zero or higher, where x>y; and forming a gate structure on sidewalls and top surface of the fin, the gate structure comprising a gate dielectric and a conductive gate line.

The lattice constant of the first crystalline material may be smaller than a lattice constant of the second crystalline material.

The first crystalline material may be SiGe and the second crystalline material is SiGe.

Source/drain regions may be epitaxially grown on opposite sides of the gate structure, respectively.

The source/drain regions may be formed of a third crystalline material having a lattice constant smaller than a lattice constant of the second crystalline material.

Methods may include etching a depression in the substrate; epitaxially growing the first crystalline material on a surface of the depression; epitaxially growing the second crystalline material on the surface of the first crystalline material to fill the depression; and using a mask to pattern the second crystalline material, the first crystalline material and the substrate by etching to form the fin.

A device isolation insulator may be formed on the substrate and around the fin to a height exceeding the height of the first crystalline material.

### BRIEF DESCRIPTION OF THE DRAWINGS

Exemplary embodiments of the inventive concept will be more clearly understood from the following detailed description taken in conjunction with the accompanying drawings in which:

FIGS. 1A through 13C are diagrams, illustrated according to a process sequence, for explaining a method of manufacturing a semiconductor device, according to an embodiment of the inventive concept;

FIGS. 1A through 1C are diagrams illustrating a substrate that is used for forming a semiconductor device;

FIGS. 2A through 2C are diagrams illustrating a form in which a hard mask is formed on the substrate;

FIGS. 3A through 3C are diagrams illustrating a form in which an opening for exposing a p-type transistor area is formed in the hard mask through an exposure process and an etch process;

FIGS. 4A through 4C are diagrams illustrating a form in which the substrate is etched by using the hard mask, in which the p-type transistor area is exposed, as an etch mask;

FIGS. 5A through 5C are diagrams illustrating an anti-punch through layer grown epitaxially while performing an in-situ doping process;

FIGS. 6A through 6C are diagrams illustrating a form in which a silicon germanium (SiGe) layer is formed by an epitaxial growth method on the anti-punch through layer grown epitaxially while performing an in-situ doping process;

FIGS. 7A through 7C are diagrams illustrating a resultant structure obtained by removing the hard mask;

FIGS. 8A through 8C are diagrams illustrating a mask that is used for forming a fin structure;

FIGS. 9A through 9C are diagrams illustrating a form in which fin structures are formed;

FIGS. 10A through 10C are diagrams illustrating a form in which a mesa structure separating an n-type transistor area from a p-type transistor area is formed before performing a deep trench isolation process of isolating the n-type transistor area from the p-type transistor area by using an insulating structure;

FIGS. 11A through 11C are diagrams illustrating a form in which an insulating structure for isolating transistors from each other is formed;

FIGS. 12A through 12C are diagrams illustrating a form in which a gate dielectric layer and a gate line are formed on the fin structures;

FIGS. 13A through 13C are diagrams illustrating a form in which a pair of source and drain electrodes are formed in each of the fin structures;

FIG. 14 is a diagram illustrating a form in which the anti-punch through layer includes a multi-layer formed of various materials;

FIG. 15 is a perspective view of a semiconductor device including a fin structure according to an embodiment of the inventive concept;

FIG. 16 is a perspective view of a semiconductor device including a fin structure according to another embodiment of the inventive concept;

FIG. 17 is a circuit diagram of an inverter according to an embodiment of the inventive concept;

FIG. 18 is a schematic block diagram of a card according to an embodiment of the inventive concept;

FIG. 19 is a schematic block diagram of an electronic system according to an embodiment of the inventive concept; and

FIG. 20 is a perspective view of an electronic apparatus according to an embodiment of the inventive concept.

### DETAILED DESCRIPTION OF THE EMBODIMENTS

Hereinafter, embodiments of the inventive concept will be described in detail with reference to the accompanying drawings. Like reference numerals in the drawings denote like elements, and thus their redundant description will be omitted.

The inventive concept will now be described more fully with reference to the accompanying drawings, in which example embodiments of the inventive concept are shown.

These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

It will be understood that although the terms “first”, “second”, etc. are used herein to describe members, regions, layers, portions, sections, components, and/or elements in embodiments of the inventive concept, the members, regions, layers, portions, sections, components, and/or elements should not be limited by these terms. These terms are only used to distinguish one member, region, portion, section, component, or element from another member, region, portion, section, component, or element. Thus, a first member, region, portion, section, component, or element described below may also be referred to as a second member, region, portion, section, component, or element without departing from the scope of the inventive concept. For example, a first element may also be referred to as a second element, and similarly, a second element may also be referred to as a first element, without departing from the scope of the inventive concept.

Unless otherwise defined, all terms (including technical and scientific terms) used herein have the same meaning as commonly understood by those of ordinary skill in the art to which the inventive concept pertains. It will also be understood that terms, such as those defined in commonly used dictionaries, should be interpreted as having a meaning that is consistent with their meaning in the context of the relevant art and will not be interpreted in an idealized or overly formal sense unless expressly so defined herein.

When a certain embodiment may be implemented differently, a specific process order may be performed differently from the described order. For example, two consecutively described processes may be performed substantially at the same time or performed in an order opposite to the described order.

In the accompanying drawings, variations from the illustrated shapes as a result, for example, of manufacturing techniques and/or tolerances, are to be expected. Thus, the embodiments of the inventive concept should not be construed as being limited to the particular shapes of regions illustrated herein but may be to include deviations n shapes that result, for example, from a manufacturing process. As used herein, the term “and/or” includes any and all combinations of one or more of the associated listed items.

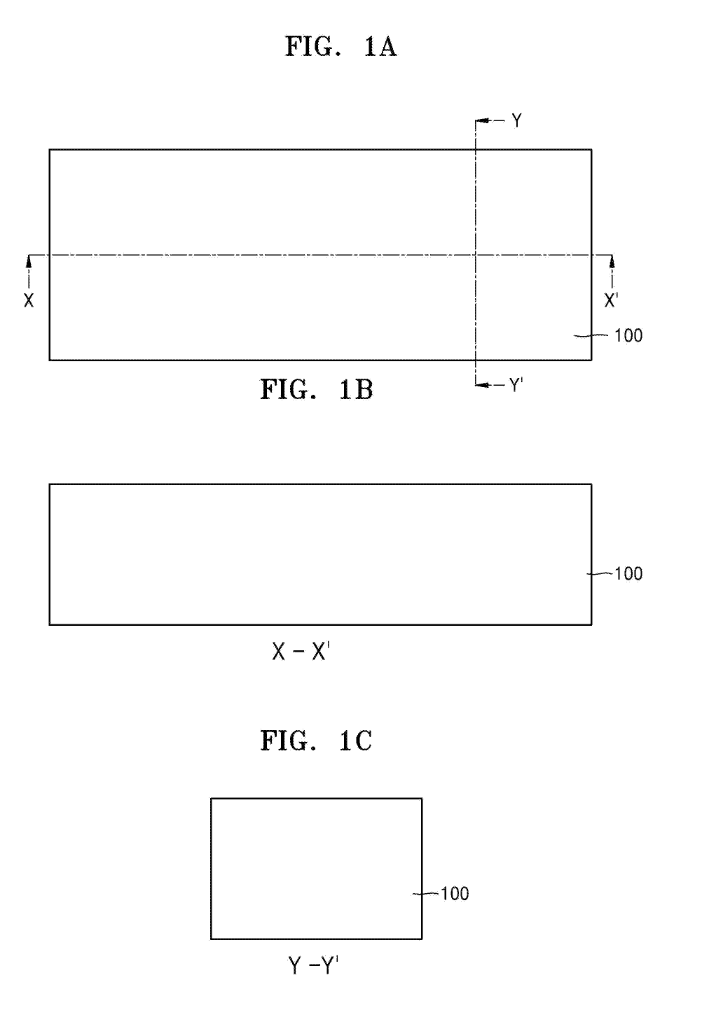

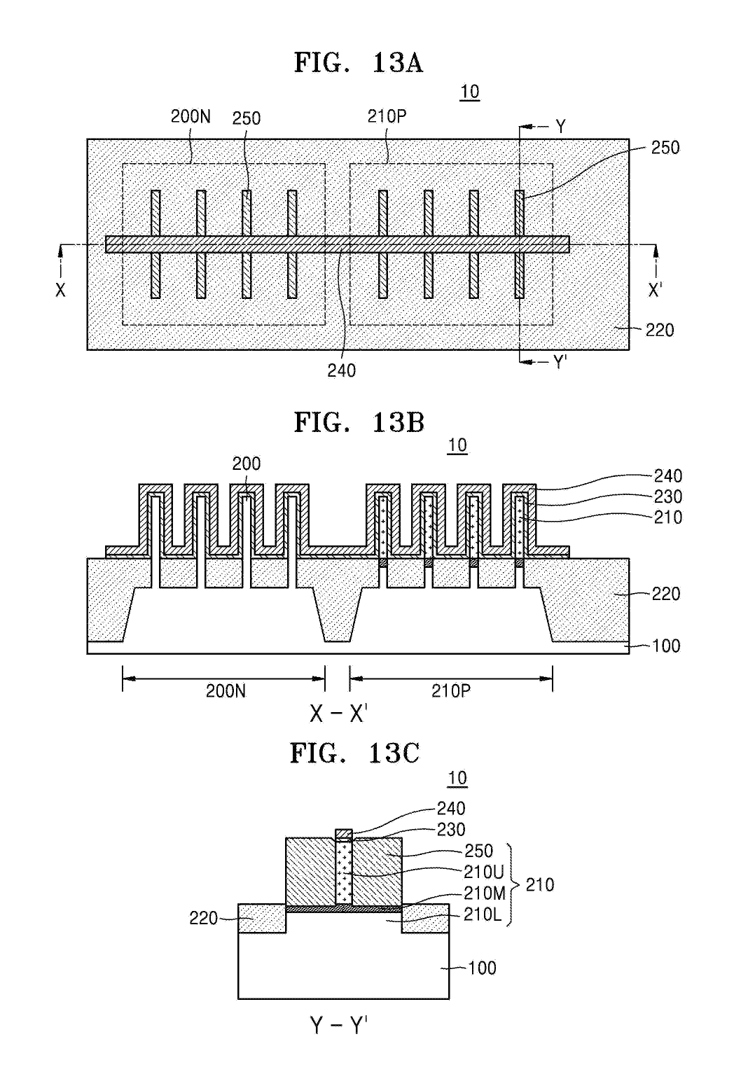

FIGS. 1A through 13C are diagrams, illustrated according to a process sequence, for explaining a method of manufacturing a semiconductor device 10 (refer to FIGS. 13A through 13C), according to an embodiment of the inventive concept.

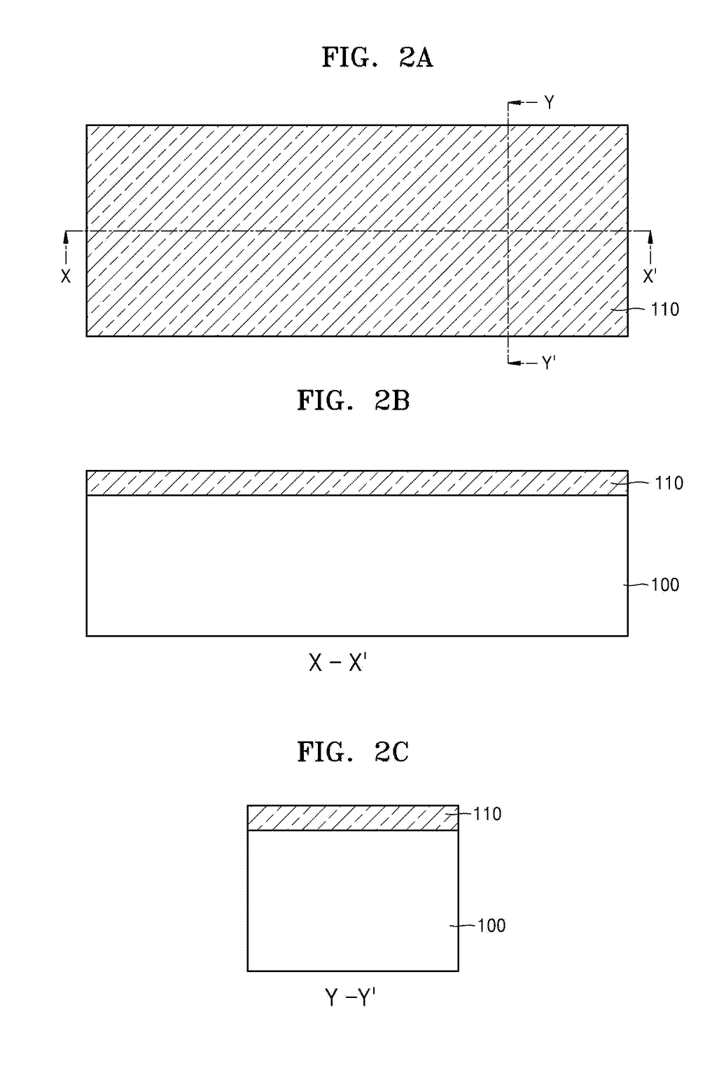

FIGS. 1A, 2A, . . . , and 13A are plan views, illustrated according to a process sequence, for explaining a method of manufacturing the semiconductor device 10. FIGS. 1B, 2B, . . . , and 13B are cross-sectional views corresponding respectively to cross-sections taken along a line X-X′ of FIGS. 1A, 2A, . . . , and 13A. FIGS. 1C, 2C, . . . , and 13C are cross-sectional views corresponding respectively to cross-sections taken along a line Y-Y′ of FIGS. 1A, 2A, . . . , and 13A.

Referring to FIGS. 1A through 1C, a substrate 100 that is used for forming the semiconductor device 10 is shown.

A substrate 100 may be a bulk silicon substrate or a silicon on insulator (SOI) substrate. The substrate 100 may comprise silicon, e.g., crystalline silicon, polycrystalline silicon, or amorphous silicon. In some embodiments, the substrate 100 may comprise germanium (Ge) (which may be crystalline, polycrystalline or amorphous), or may include a compound semiconductor, such as silicon germanium (SiGe), or silicon carbide (SiC). In the current embodiment, a case in which the substrate 100 includes silicon is described as an example.

Referring to FIGS. 2A through 2C, a hard mask 110 is formed on the substrate 100.

The hard mask 110 functions as a mask that is used for etching the substrate 100 in a subsequent process. The hard mask 110 may also be a material for forming an anti-punch through layer. The hard mask 110 may also allow formation of an upper fin structure through epitaxial growth. Accordingly, the hard mask 110 may be formed of a material that has high etch selectivity and may tolerate an epitaxial growth process.

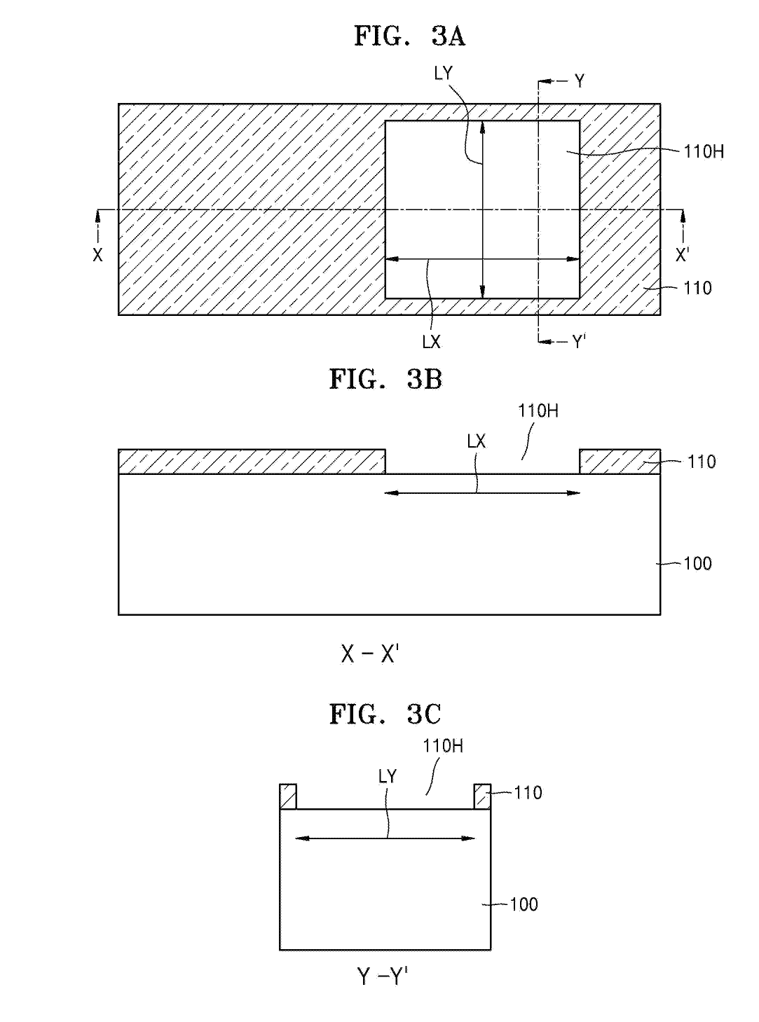

Referring to FIGS. 3A through 3C, an opening 110H for exposing a transistor area (in this example, a p-type transistor area) is formed in a hard mask 110 through an exposure process and an etch process. For example, a photoresist layer may be deposited on the hard mask 110 layer, selectively irradiated with light to expose portions of the photoresist and selectively etch the photoresist layer corresponding to its exposure. The patterned photoresist may have a pattern like the pattern of the hard mask 110 in FIG. 3A and be used to etch hard mask 110 to form the pattern of the hard mask 110.

A photoresist layer used in the exposure process may be a positive type or a negative type and is removed after performing the etch process on the hard mask 100. In

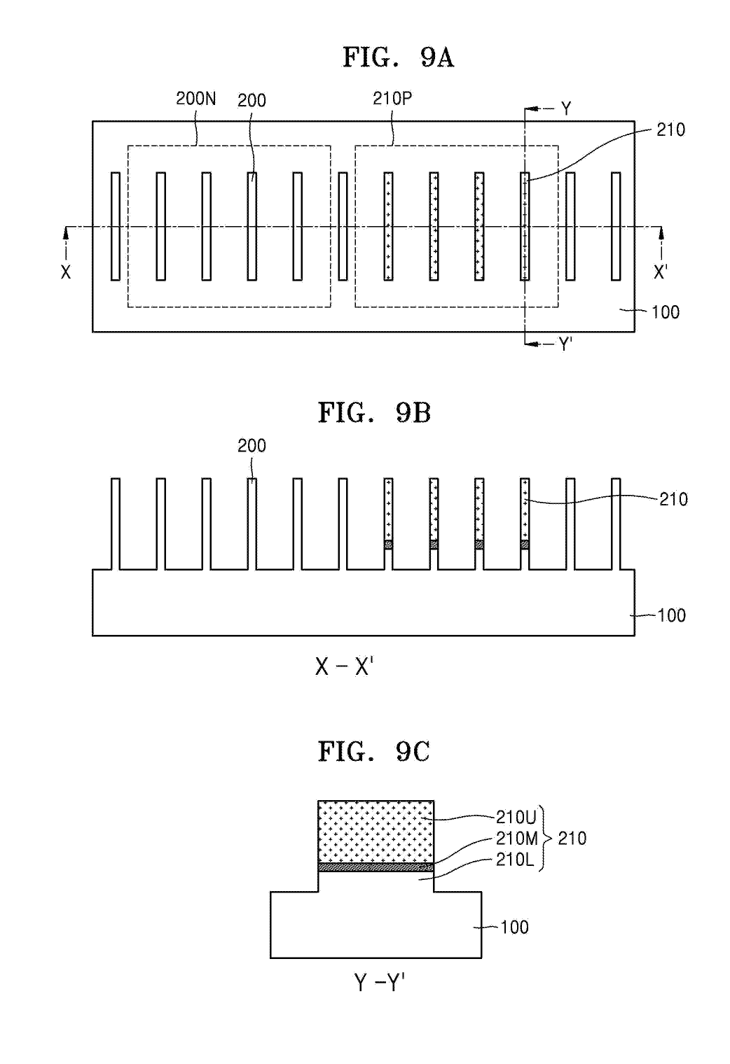

FIG. 3A, a Y direction length LY of the opening 110H for exposing the p-type transistor area is larger than that of a fin structure 210 (refer to FIGS. 9A through 9C) of the p-type transistor area, which is to be formed in a subsequent process, and an X direction length LX of the opening 110H for exposing the p-type transistor area is related to the number of fin structures 210 (refer to FIGS. 9A through 9C) of the p-type transistor area, which is to be formed in a subsequent process.

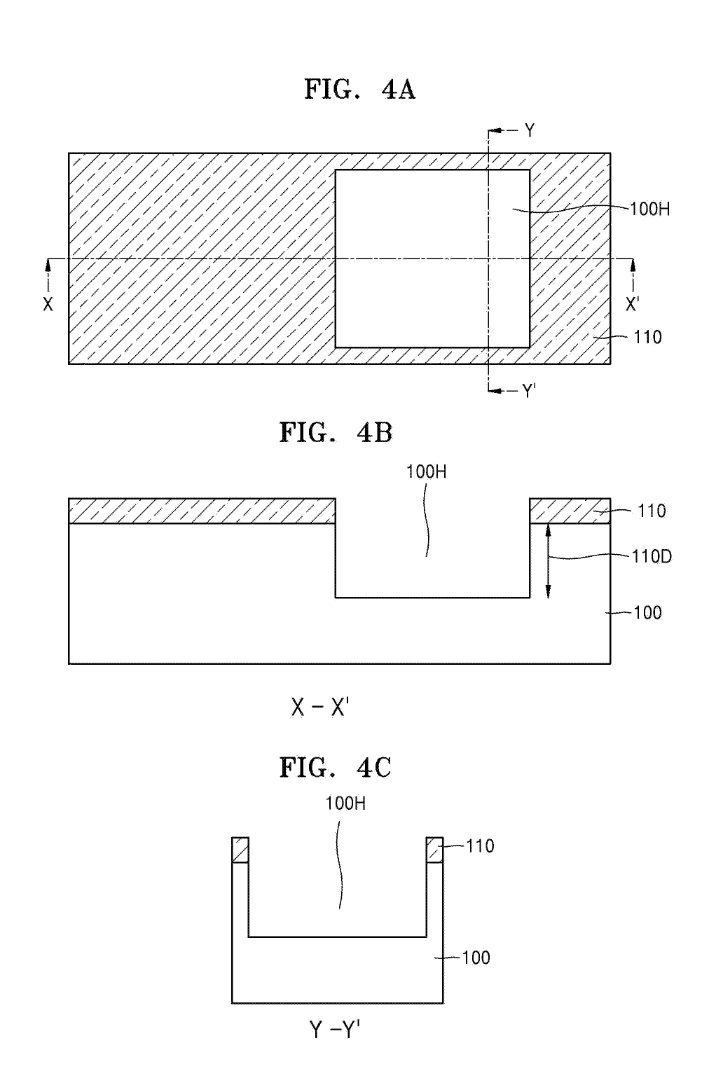

Referring to FIGS. 4A through 4C, the substrate 100 is etched by using the hard mask 110, in which the p-type transistor area is exposed, as an etch mask.

The depth 110D of an etched portion of the substrate 100 may determine the height of an anti-punch through layer 210M (refer to FIGS. 9A through 9C) and the height of an upper fin structure 210U (refer to FIGS. 9A through 9C) in subsequent processes. Since the height of the fin structure 210U is closely related to electrical device characteristics, the depth 110D of the etched portion of the substrate 100 may influence characteristics of the electrical device to be formed.

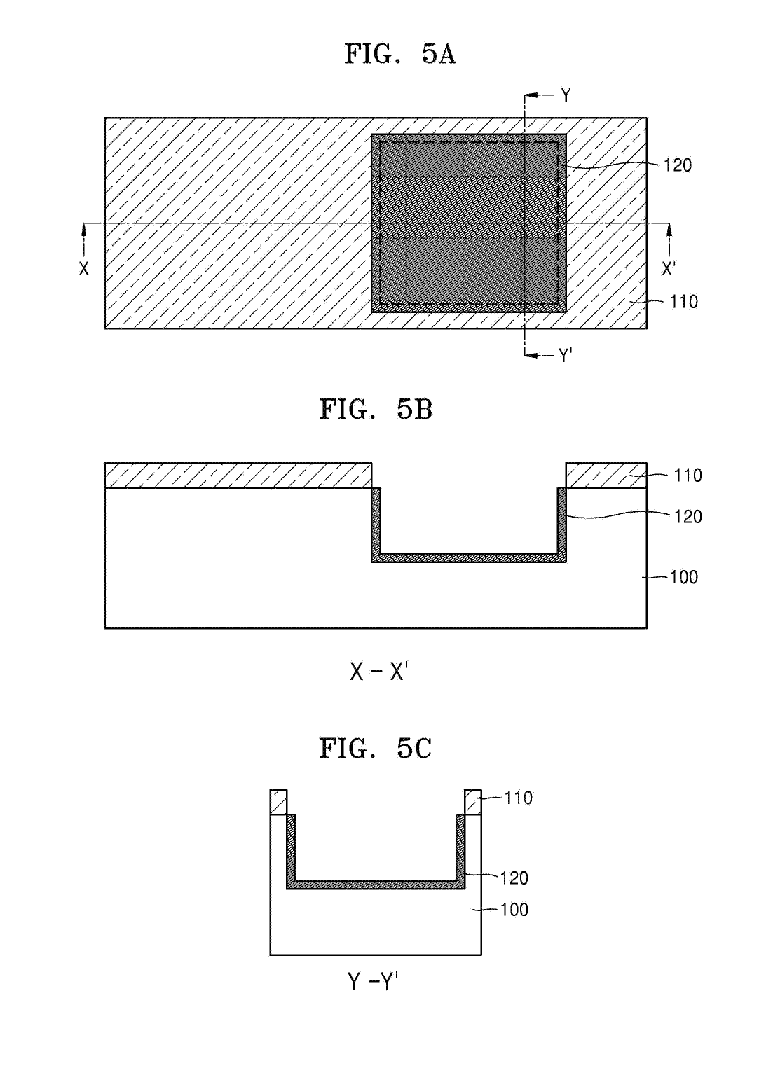

Referring to FIGS. 5A through 5C, an anti-punch through layer 120 may be grown epitaxially while performing an in-situ doping process.

The anti-punch through layer 120 prevents punch through occurring in a fin-type field effect transistor (FinFET) and also functions as a junction isolation layer.

The anti-punch through layer 120 may be formed of an epitaxially grown material and may be silicon (Si), silicon germanium (SiGe), or a material that is suitable for semiconductor devices. The anti-punch through layer 120 may be epitaxially grown so that the substrate 100 does not have a lattice defect or has minimal lattice defects. The anti-punch through layer 120 may include a single layer formed of a single material (e.g., single homogeneous material) or a multi-layer formed of several layers of various materials. The anti-punch through layer 120 may be formed so as to prevent dopants used through an in-situ doping process from moving to another portion of the fin structure by a subsequent heat treatment process or the like.

The anti-punch through layer 120 in the p-type transistor area may be doped with n-type dopants, and a doping concentration may have a value between 10¹⁷/cm³ and 10²¹/cm³. The doping concentration of the anti-punch through layer 120 may assist preventing punch through or reducing any punch through to an acceptable level. The value of the doping concentration is an example and may have a values in another range in consideration of characteristics of a semiconductor device and a doping concentration of a source and drain. The anti-punch through layer 120 may have a dopant concentration that is higher than that of the upper fin structure 210U to be formed on the anti-punch through layer 120, as described below.

As the doping using n-type dopants is performed through an in-situ doping process during an epitaxial growth process (e.g., at the same time while growing the semiconductor epitaxial layer of the anti-punch layer 120, such as within the same process chamber), there may be various advantages compared to performing a doping by using an ion implantation process.

First, a doping concentration profile may have one of various forms as well as a Gaussian distribution that is a regular distribution. For example, a doping concentration may be concentrated only in an upper portion or lower portion of the anti-punch through layer 120 or may be concentrated in both the upper and lower portions of the anti-punch through layer 120. That is, various doping concentration profiles may be obtained.

Second, since an activation heat treatment process that is performed to activate dopants when performing doping by using the ion implementation process may be omitted, a manufacturing process may be simplified and thus a throughput thereof may be increased, thereby decreasing manufacturing costs.

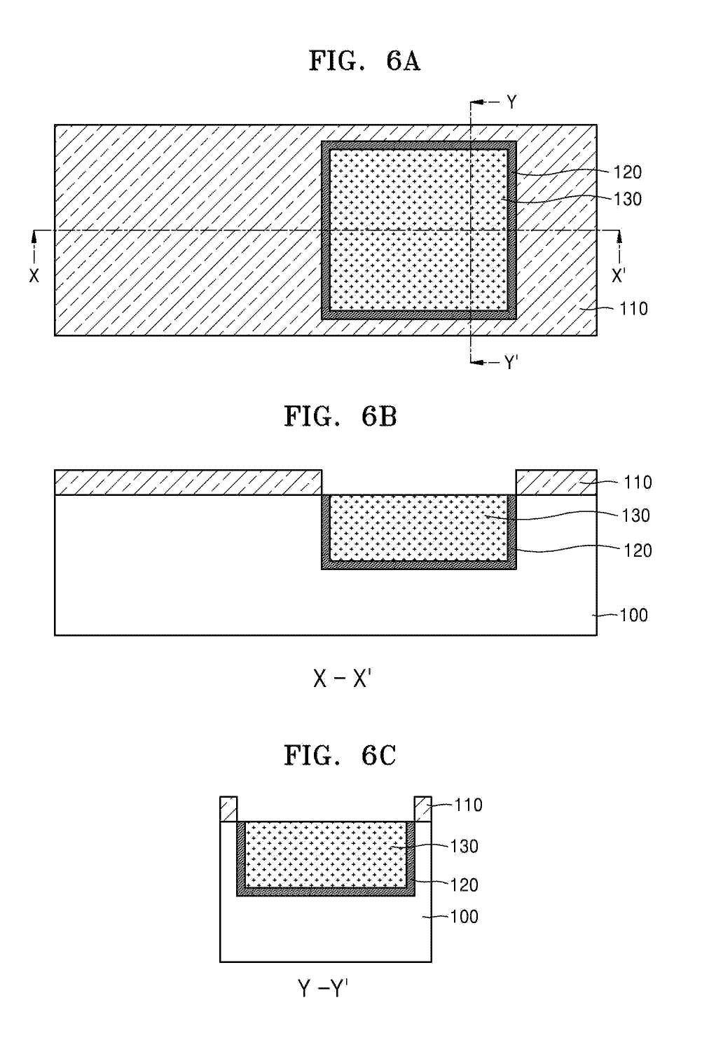

Referring to FIGS. 6A through 6C, a SiGe layer 130 is epitaxially grown on the anti-punch through layer 120 while performing an in-situ doping process.

The SiGe layer 130 may be formed by using the same semiconductor equipment that used in a process of forming the anti-punch through layer 120. In this case, the following various advantages are provided.

First, a manufacturing process may be simplified and thus a throughput thereof may be increased, thereby decreasing a manufacturing cost.

Second, the same process chamber may maintain a seal (e.g., a vacuum seal) so as not to expose the device structure (e.g., as shown in FIG. 5A-5C) to atmosphere or otherwise require transfer. Therefore, contamination may not occur during movement between semiconductor equipment. Since defects that may occur when performing an epitaxial growth process should be minimized, the same semiconductor equipment may be used to obtain the SiGe layer 130 having excellent physical characteristics. However, the inventive concept is not limited thereto, and the SiGe layer 130 may be formed by using a different semiconductor equipment from that used in a process of forming the anti-punch through layer 120.

The SiGe layer 130 may be formed so as to maximize or otherwise increase a strain while minimizing defects. The mobility of holes (carriers) in a channel area of a p-type transistor has an influence on device characteristics, and applying a strain to the channel area may increase the mobility of holes and influence device characteristics. Since SiGe has a relatively large lattice constant compared to Si, a strain occurs by a stress caused due to the mismatched lattice constants, and thus mobility characteristics of holes are improved. The strain may be fully preserved or slightly relaxed while performing subsequent processes.

The SiGe layer 130 will be used to form the upper fin structure 210U (refer to FIG. 9C) in a subsequent process. The upper fin structure 210U may not be doped or may be doped with n-type dopants to correspond to characteristics of the p-type transistor. The doping with n-type dopants may be performed by an ion implantation process or another method.

The upper surface of the SiGe layer 130 may be or may not be level with the upper surface of the substrate 100 in consideration of a subsequent process. The position of the upper surface of the SiGe layer 130 may be adjusted according to the degree of process difficulty that is caused due to a topology difference from a fin structure 200 (refer to FIGS. 9A through 9C) of an n-type transistor area to be formed in subsequent processes.

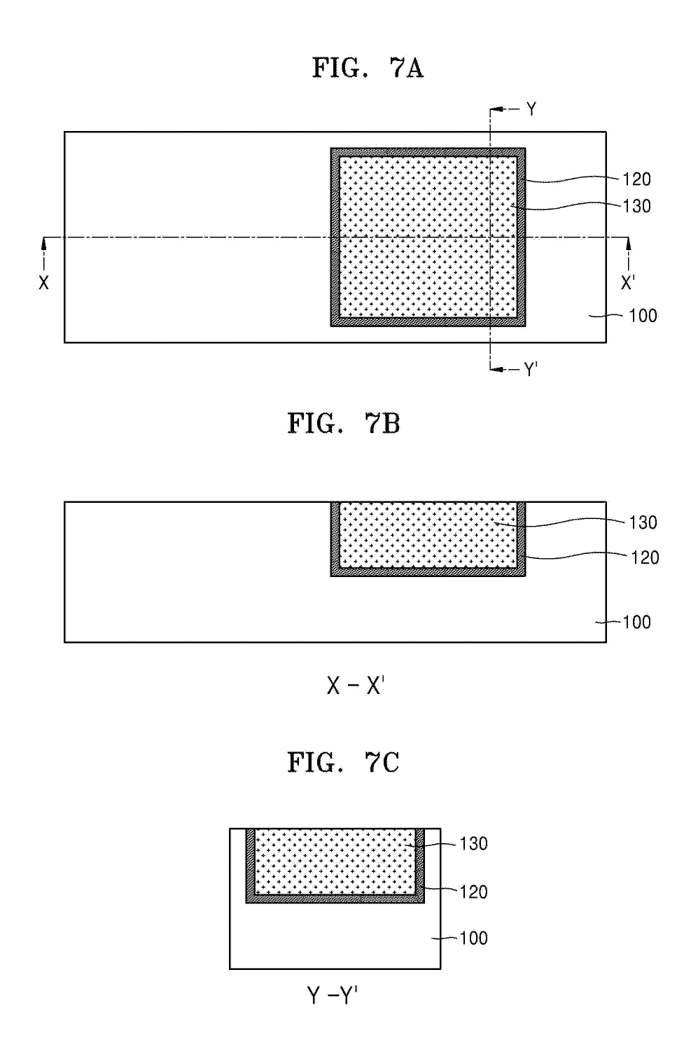

Referring to FIGS. 7A through 7C, a resultant structure obtained by removing the hard mask 110 is shown.

As noted above, the hard mask 110 functions as a mask that is used for etching the trench or depression in a region where p-type transistors will be formed, and the hard mask 110 also functions as a blocking mask so that the anti-punch through layer 120 and the SiGe layer 130 are not formed on another portion of the substrate 100 while epitaxially growing the anti-punch through layer 120 and the SiGe layer 130.

The hard mask 110 may be removed by an etching process and impurities of the surface of the resultant structure are removed through a cleaning process. The etching process may be a planarization etch (e.g., chemical mechanical planarization) or a wet etch, e.g.

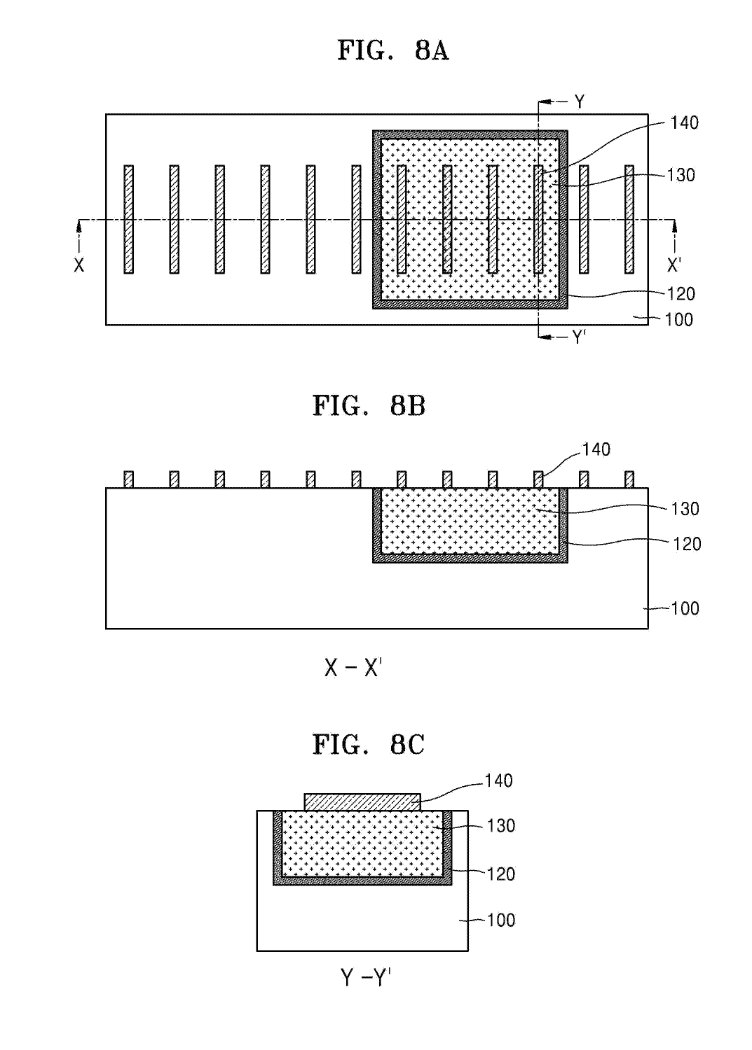

Referring to FIGS. 8A through 8C, a mask 140 that is used for forming a fin structure is formed.

The mask 140 may be a photoresist layer (formed by patterning a photoresist material using photolithography followed by a selective etch of the photoresist material, as described herein) or a hard mask (formed by depositing a hard mask material and patterning the same, e.g., with a patterned photoresist layer). A mask having high selectivity with respect to Si and SiGe is selected in consideration of the aspect ratio of the fin structure. If desired, an etch process for forming the fin structure may be performed by using a multi-layered mask rather than a single-layered mask for mask 140.

Referring to FIGS. 9A through 9C, a plurality of first fin structures 200 and a plurality of second fin structures 210 are formed.

The plurality of first fin structures 200 are fin structures formed in an n-type transistor area 200N and the plurality of second fin structures 210 are fin structures formed in a p-type transistor area 200P. The plurality of first fin structures 200 are formed by performing an etch of the substrate 100 in the n-type transistor area 200N, patterned using corresponding elements of mask 140 overlying the same. The plurality of second fin structures 210 are formed by performing an etch of the SiGe layer 130, the anti-punch through layer 120 and the substrate 100 using corresponding elements of mask 140 overlying the same.

The plurality of first fin structures 200 formed in the n-type transistor area 200N are formed of the same material as the substrate 100. A lower fin structure 210L of each of the plurality of second fin structures 210 formed in the p-type transistor area 200P is formed of the same material as the substrate 100, but an upper fin structure 210U of each of the plurality of second fin structures 210 is formed of epitaxially grown SiGe. The material of each first fin structure 200, the material of the lower fin structure 210L of each second fin structure 210, and the material of the upper fin structure 210U of each second fin structure 210 may have different doping concentrations. The anti-punch through layer 210M may have a dopant concentration that is higher than that of the upper fin structure 210U. The upper fin structure 210U may not be doped or may be doped with n-type dopants.

By forming channel areas of the second fin structures 210 of the p-type transistor area 200P by using a material that is different from that of channel areas of the first fin structures 200 of the n-type transistor area 200N, a semiconductor device having a dual channel structure may be formed.

In the semiconductor device having the dual channel structure, a channel area of an n-type transistor and a channel area of a p-type transistor are formed to have different fin structures to thereby improve operating characteristics of the semiconductor device. In the current embodiment of the inventive concept, a channel area of an n-type transistor is formed of Si and a channel area of a p-type transistor is formed of SiGe, and thus the performance of electrons and holes which have different mobilities may be improved and manufacturing processes may be simplified, thereby reducing a manufacturing cost.

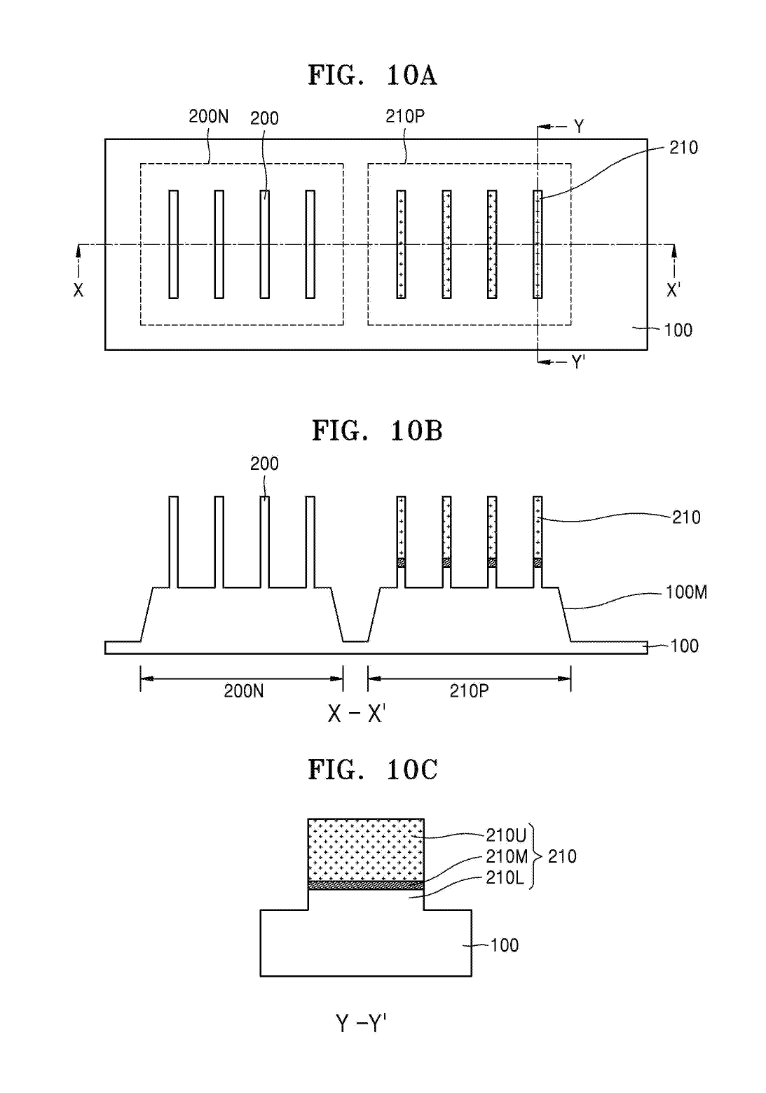

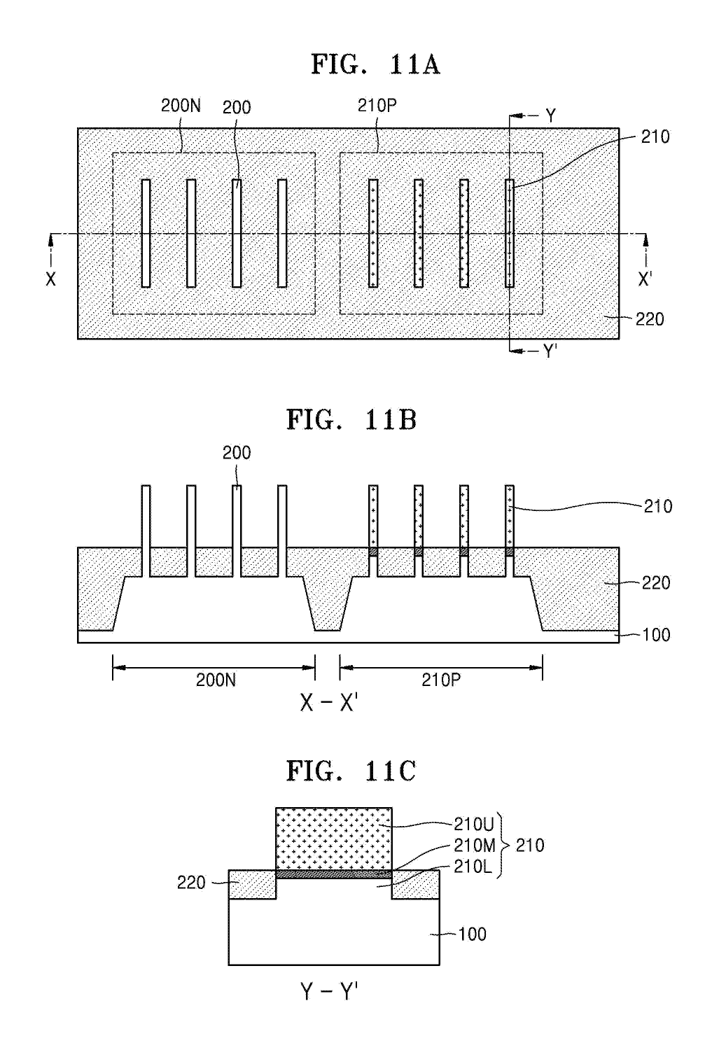

Referring to FIGS. 10A through 10C, a mesa structure 100M that separates the n-type transistor area 200N from the p-type transistor area 200P is formed before performing a deep trench isolation process of isolating the n-type transistor area 200N from the p-type transistor area 200P by using an insulating structure 220 shown in FIGS. 11A through 11C.

In order to prevent the movement of dopants between the n-type transistor area 200N and the p-type transistor area 200P when using the bulk silicon substrate 100 and improve electrical characteristics of transistors, the mesa structure 100M is formed by performing a process of separating the n-type transistor area 200N from the p-type transistor area 200P.

Referring to FIGS. 11A through 11C, the insulating structure 220 for isolating transistors from each other is formed. The insulating structure 220 may be formed by depositing an insulating layer to fill the trenches between the first and second type fin structures 200 and 210 followed by an etch-back of the insulating layer to etch back the top surface of the insulating layer to expose upper portions of the first and second type fin structures 200 and 210 (e.g., as shown).

The insulating structure 220 functions as a deep trench isolation structure for isolating the n-type transistor area 200N from the p-type transistor area 200P. Also, the insulating structure 220 isolates the first fin structures 200 of the n-type transistor area 200N from each other and isolates the second fin structures 210 of the p-type transistor area 200P from each other. The insulating structure 220 may act to isolate fin type active regions (here, the first fin structures 200 and second fin structures 210) from each other.

The upper surface of the insulating structure 220 may have the same level as the boundary between the anti-punch through layer 210M and the upper fin structure 210U in the second fin structures 210 of the p-type transistor area 210P. Since a channel is formed in a portion formed of SiGe, that is, the upper fin structures 210U, the upper fin structures 210U should be exposed from the insulating structure 220 (e.g., the entire upper fin structure 210U or a majority of the upper fin structure 210U may be exposed).

The insulating structure 220 may include a silicon oxide layer, a silicon nitride layer, a silicon oxynitride layer, or a combination thereof

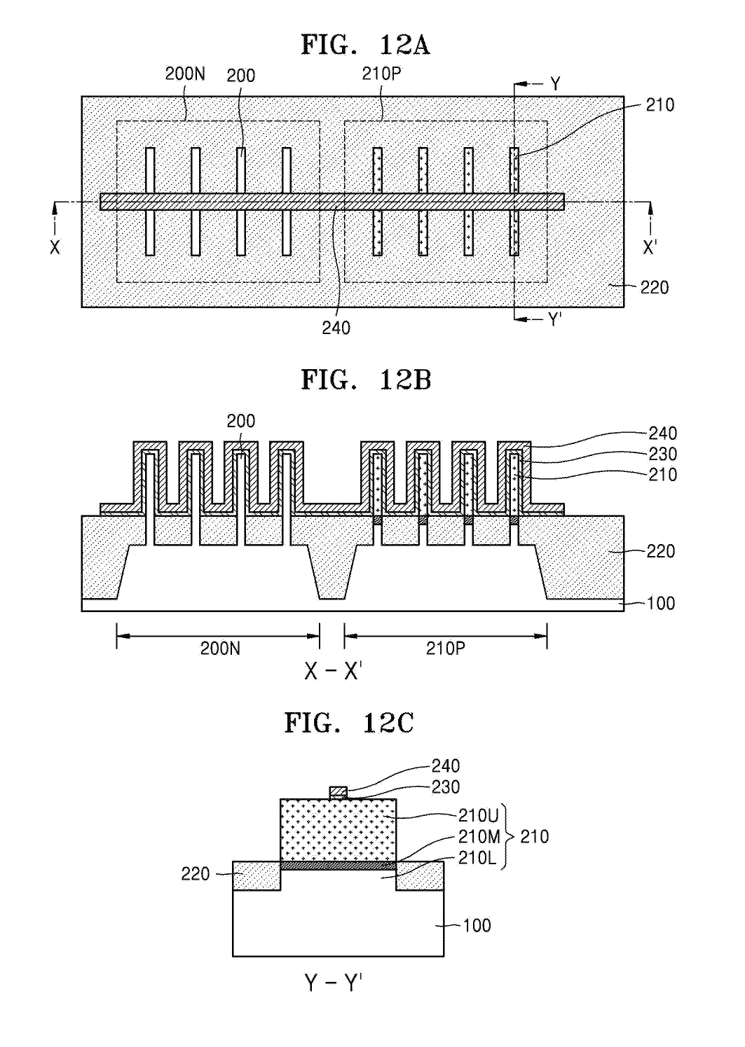

Referring to FIGS. 12A through 12C, a gate dielectric layer 230 and a gate line 240 are formed on the first and second fin structures 200 and 210.

The gate dielectric layer 230 and the gate line 240 may form a gate structure and extend to intersect the first and second fin structures 200 and 210. In FIGS. 12A and 12B, the same gate structure 230/240 is shown formed on both of the first and second fin structures 200 and 210. However, it will be recognized that discrete, unconnected gate structures (which may be patterned out of the same gate dielectric material layer and gate line material layer) may be formed over the first and second fin structures 200 and 210, as well as elements thereof. For example, a first gate structure may be formed only over some or all of the first fin structures 200 (and not over any of the second fin structures 210) and a second gate structure may be formed only over some or all of the second fin structures 210 (and not over any of the first fin structures 200). The gate structures may be formed by conformally forming a gate dielectric material layer on the surface of the structure of FIGS. 11A to 11C and depositing a gate line conductor layer on the surface of the gate dielectric layer. The gate dielectric material layer and gate line conductor layer may be patterned (e.g., etched using a photoresist mask or a hard mask as described herein) to form the gate structure 230/240 as shown. As shown in FIG. 12B, the gate dielectric layer 230 and the gate line 240 are formed along (and here, directly on) three surfaces of the first and second fin structures 200 and 210, that extend above the insulating structure 220, and thus, a structure of a FinFET (e.g., a tri-gate transistor) is obtained.

The gate dielectric layer 230 may include at least one selected from a silicon oxide layer, a silicon nitride layer, a silicon oxynitride layer, an oxide/nitride/oxide (ONO) layer, and a high-k dielectric layer having a dielectric constant that is higher than that of the silicon oxide layer.

The gate dielectric layer 230 may be high-k dielectric, having a dielectric constant of 10 or greater. In some examples, the gate dielectric layer 230 may have a dielectric constant of about 20 to about 25. In some embodiments, the gate dielectric layer 230 may be formed of at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric layer 230 may be formed of HfO₂, Al₂O₃, HfAlO₃, Ta₂O₃, or TiO₂.

In some embodiment, the gate line 240 may be formed of at least one selected from titanium (Ti), titanium nitride (TiN), tantalum (Ta), tantalum nitride (TaN), tungsten (W), tungsten nitride (WN), titanium silicon nitride (TiSiN), and tungsten silicon nitride (WSiN).

FIGS. 13A through 13C, a pair of source and drain electrodes 250 (hereinafter, referred to as a source and drain pair 250) are formed in each of the first and second fin structures 200 and 210. For example, the portion of each fin structure 210 lying under the gate structure 230/240 may remain while SiGe portions of each fin structure 210 outside the gate structure 230/240 are removed by an etching process using the gate structure 230/240 as a mask. In the example illustrated in FIGS. 13A-13C, the SiGe portions of each fin structure 210 are completely removed at locations on either side of the gate structure 230/240 to expose the anti-punch through layer 210M, but less may be removed so some SiGe portion of fin structure 210 remains at locations outside the gate structure 230/240 (in addition to that under the gate structure 230/240). These etched portions of each fin structure 210 outside the gate structure 230/240 may then be used to epitaxially grow source and drain electrodes 250, such as by epitaxially growing (on the anti-punch through layer 210M) a semiconductor material to provide a compressive strain to the adjacent channel region. This epitaxially grown semiconductor material may be a crystalline material having a lattice constant smaller than that of the crystalline material of the upper fin structure 210 and, may be, e.g., silicon, or silicon germanium (the germanium content may be less than the silicon content, e.g., Si_{i-y}Ge_{y} where y>40%, such as y=20% +/−5%). Both the source and drain electrodes 250 and the upper fin structure 210 may be formed of SiGe in some examples. The epitaxially grown SiGe source and drain regions 250 may have less Ge per Si than that of the upper fin structure 210U (e.g., the source and drain regions 250 may be formed of Si_{i-y}Ge_{y} the upper fin structure 210 may be formed of Si₁₋ₓGeₓ, where y<x). The epitaxially grown source and drain electrodes 250 may be doped in situ with p-type dopant, such as by in-situ doping the source and drain electrodes with boron (B) as they are being epitaxially grown. In an alternative embodiment, the source and drain electrodes 250 may be formed by doping the SiGe portion of the fin structure 210 at locations outside (i.e., not underneath) the gate structure 230/240 with a p-type dopant (such as by performing an ion implant-type doping of boron using the gate structure 230/240 as a mask). Source drain electrodes 250 of the first fin structures 200 in the n-type transistor area 200N may be formed by a similar process, such as by performing an etch of portions of the first fin structures outside the gate structure 230/240 using the gate structure 230/240 as a mask and epitaxially growing a semiconductor material to provide a tensile strain to the adjacent channel region. For example, the epitaxially grown semiconductor material may be silicon carbon. The epitaxially grown semiconductor material may be doped in situ with an n-type dopant, such as arsenic (As). Alternatively, the source drain regions 250 of the first structures 200 may be formed by performing an ion implantation of n-type dopants into the first fin structure portions that are exposed outside the gate structure 230/240 using the gate structure 230/240 as a mask (it should be noted that this alternative may be implemented with the epitaxially grown source and drain electrodes 250 of the p-type region or with the implanted doped source and drain electrodes 250 of the p-type region). Forming the source and drain pairs 250 of the first and second fin structures 200 and 210 may be formed sequentially (in either order) where the fin structures not being processed to generate the source and drain pair is protected with a mask (that may be later removed).

The source and drain pair 250 may be formed after forming the gate dielectric layer 230 and the gate line 240 or before forming the gate dielectric layer 230 and the gate line 240. A raised source/drain structure may improve the performance of transistors. In some examples, gate dielectric layer 230 and gate line 240 may be dummy gate structures. For example, sidewall spacers may be formed on the gate structure 230/240 shown in FIGS. 13A-13C, and a interlayer dielectric layer may be deposited thereon and planarized to expose the gate structure 230/240 (note the gate structure may also include a capping layer—non shown—formed over the gate line and patterned with the gate dielectric layer 230 and gate line 240 and this planarization may etch to expose this capping layer). The gate structure may be removed (sidewall spacers may remain). A real gate structure comprising a real gate dielectric 230′ and real gate line 240′ may then be formed in a trench defined by the sidewall spacers and interlayer dielectric by sequentially depositing a real gate dielectric material layer and a real gate line material layer and planarizing the same to remove portions deposited on top surfaces of the interlayer dielectric layer (outside the trench). Example formation of dummy gate structures and subsequent formation of real gate structures, as well as epitaxially growing source/drain regions on recessed portions of a fin type active region, is disclosed in U.S. patent application Ser. No. 14/262,712, the disclosure of which is hereby incorporated in its entirety (this application also describes a connection between two adjacent source/drain regions which may be optionally implemented in the embodiments of the present disclosure).

As shown in FIG. 13C, the source and drain pair 250 having an epitaxially grown source/drain structure (which may be a raised source/drain structure and may extend above a top surface of the portion of the fin forming the channel region under the gate structure 230/240) is formed by etching a portion of the upper fin structure 210U and growing an epitaxial layer in the etched portion. In this case, in order to improve characteristics of the semiconductor device, the source and drain pair 250 may be formed to have a form in which the upper surface of the source and drain pair 250 is higher or raised as compared to the top surface of the remaining portions of the second fin structures 210 as well as the top surfaces of the first fin structures 200 and 210.

Recently, when manufacturing a semiconductor device, a process of generating a strain is used to improve mobility characteristics of carriers in channel areas. In the current embodiment of the inventive concept, a strain may be implemented by the following method.

First, the upper fin structure 210U is formed of biaxially compressively strained SiGe to apply a strain to a channel area. After the second fin structures 210 are formed, the biaxial compressive strain is converted into a uniaxial compressive strain, and thus, the performance of the semiconductor device may be greatly improved.

Second, the source and drain pair 250 is formed in an embedded SiGe source/drain form and a compression strain is applied to a channel area to improve the mobility of holes and a driving voltage.

The anti-punch through layer 210M may prevent a punch through in the FinFET and also functions as a junction isolation layer. The punch through is a phenomenon in which a depletion area of a source and a depletion area of a drain adjoin each other due to a short channel effect and thus a gate voltage may not control (or not fully control) when a current may flow, and thus, a function of a transistor is lost or impaired. The short channel effect may occur as a channel area of a transistor decreases according to a trend that the sizes of elements of semiconductor devices decrease due to the desire for high integration density and lower power consumption. Although punch through may be more serious in p-type transistors compared to n-type transistors, this invention is also applicable to n-type transistors where formation of a hole 100H, anti-punch through layer 120 and an epitaxially grow semiconductor material 130 is instead or also performed in the n-type transistor area 200N. As the remaining structure and process steps may be the same as that descried herein with respect to the p-type transistor area 2210P, a detailed description is omitted. In addition, the anti-punch through layer 210M may prevent a leakage current between a drain and a body.

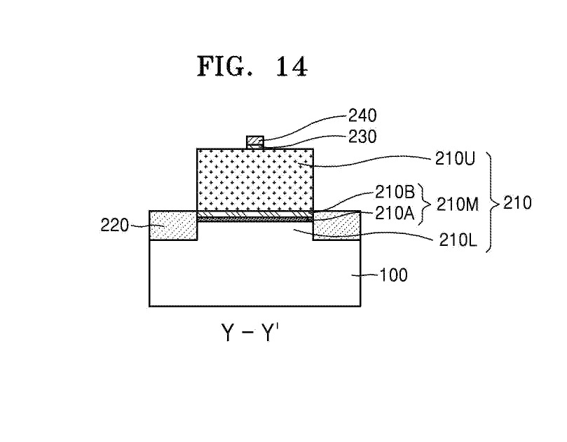

FIG. 14 is a diagram illustrating a form in which the anti-punch through layer 210M includes a multi-layer formed of various materials.

FIG. 14 shows a cross-section taken along the line Y-Y′ of FIG. 12A where the anti-punch through layer 210M is formed differently from that described with respect to the previous embodiment. Other elements of the previous embodiment may be the same as previously described, including their alternatives.

Referring to FIG. 14, the anti-punch through layer 210M includes a first layer 210A and a second layer 210B. For example, the first layer 210A may be formed of Si, and the second layer 210B may be formed of SiGe, both of which may be epitaxially grown. If desired, the anti-punch through layer 210M may include three layers or more. Source and drain regions may be formed in fin structure 210 by doping upper fin structure 210 (e.g., via ion implantation) or by performing an etch back of the upper fin structure 210 and epitaxially growing raised source drain regions 250 as described with respect to FIGS. 13A-13C.

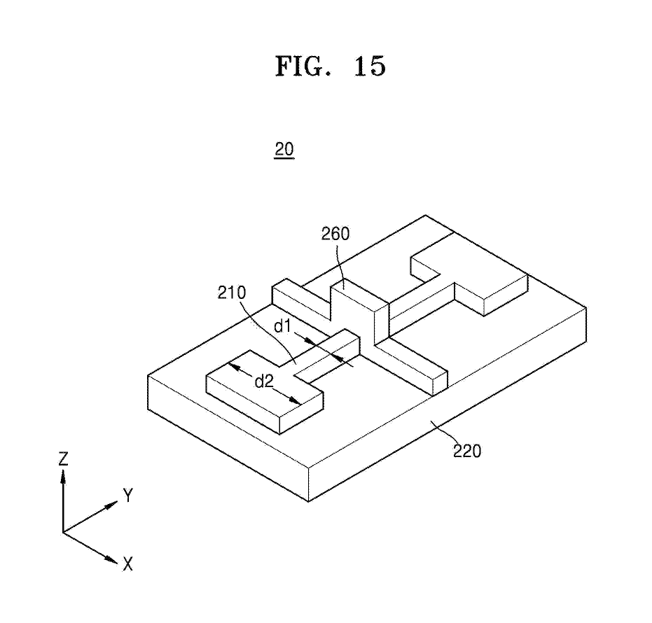

FIG. 15 is a perspective view of a semiconductor device 20 including a fin structure according to an embodiment of the inventive concept.

In the semiconductor device 20, a fin structure 210 is formed on an insulating structure 220. A gate structure 260 is formed on the fin structure 210 and the insulating structure 220. The gate structure 260 may correspond to the gate dielectric layer 230 and the gate line 240 illustrated and described with respect to FIG. 12B (including the structure resulting from the alternative embodiment due to previous formation of a dummy gate structure). In FIG. 15, a substrate under the insulating structure 220 is not illustrated in convenience. Embodiments described with respect to FIGS. 1-14 and their alternatives may be implemented in the layout structure illustrated in FIG. 15.

The fin structure 210 extends in a second direction (the Y direction of FIG. 15), and the gate structure 260 extends in a first direction (the X direction of FIG. 15) that is perpendicular to the second direction. As illustrated in FIG. 15, the fin structure 210 may have different widths d1 and d2 in the second direction at both sides of the gate structure 260.

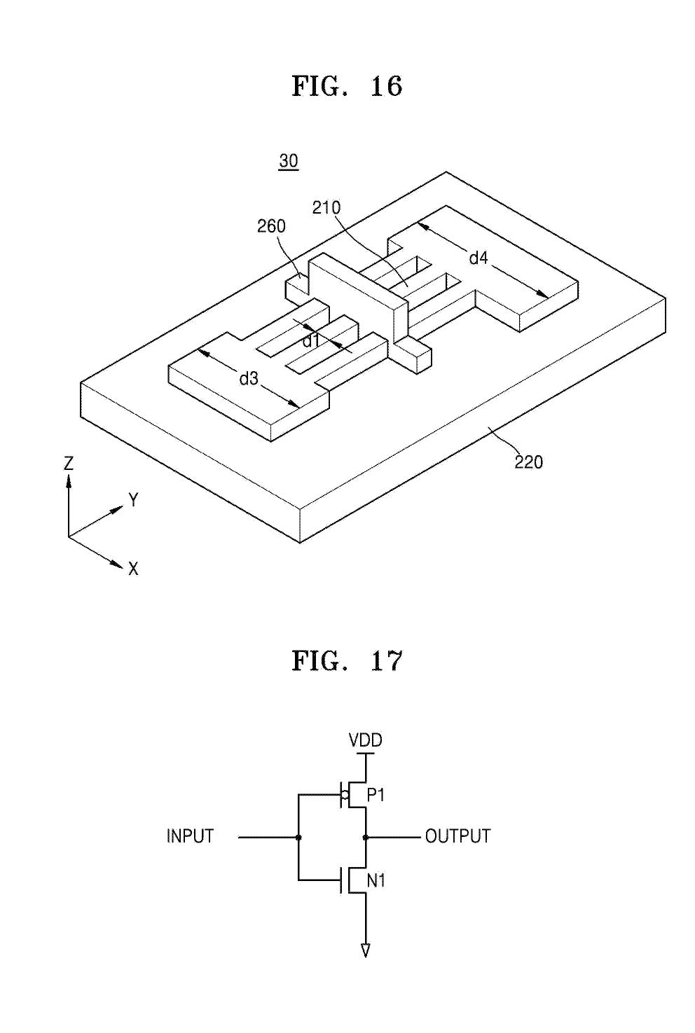

FIG. 16 is a perspective view of a semiconductor device 30 including a fin structure according to another embodiment of the inventive concept.

In the semiconductor device 30, a plurality of fin structures 210 are formed on an insulating structure 220. A gate structure 260 is formed on the plurality of fin structures 210 and the insulating structure 220. The gate structure 260 may correspond to the gate dielectric layer 230 and the gate line 240 illustrated and described with respect to FIG. 12B (including the structure resulting from the alternative embodiment due to previous formation of a dummy gate structure). In FIG. 16, a substrate under the insulating structure 220 is not illustrated in convenience. Embodiments described with respect to FIGS. 1-14 and their alternatives may be implemented in the layout structure illustrated in FIG. 15.

The fin structures 210 extend in a second direction (the Y direction of FIG. 16), and the gate structure 260 extends in a first direction (the X direction of FIG. 16) that is perpendicular to the second direction. As illustrated in FIG. 16, the fin structures 210 may have different widths d1, d3, and d4 in the second direction at both sides of the gate structure 260. In some examples, d3 and d4 may be the same value. In addition, the fin structures 210 may be combined with each other at both sides of the gate structure 260 as shown to form a single combined structure, such as a single transistor formed by combining transistor parts in parallel (e.g., source/drains on a first side of the gate structure 260 are connected, source/drains on a second side of gate structure 260 are connected and the gate structure 260 forms a gate over each of the fins).

FIG. 17 is a circuit diagram of an inverter including a semiconductor device according to an embodiment of the inventive concept.

Referring to FIGS. 17 and 13A through 13C, the inverter is formed of a CMOS transistor that includes a transistor P1 of the p-type transistor area 210P and a transistor N1 of the n-type transistor area. One or both of transistor P1 of the p-type transistor area 210P and the transistor N1 of the n-type transistor area may include a FinFET according to the above-described embodiments.

The transistor P1 of the p-type transistor area 210P and the transistor N1 of the n-type transistor are connected in series between an operating voltage VDD and a ground voltage GND, and an input signal IN is input to both the gate of the transistor P1 and the gate of the transistor N1. An output signal OUT is output from a connection node between the drain of the transistor P1 and the drain of the transistor N1.

The operating voltage VDD is applied to the source of the transistor P1, and the ground voltage VSS is applied to the source of the transistor N1. The inverter inverts the input signal IN and outputs the output signal OUT. In other words, when a signal having a logic level ‘1’ is input as the input signal IN of the inverter, a signal having a logic level ‘0’ is output as the output signal OUT.

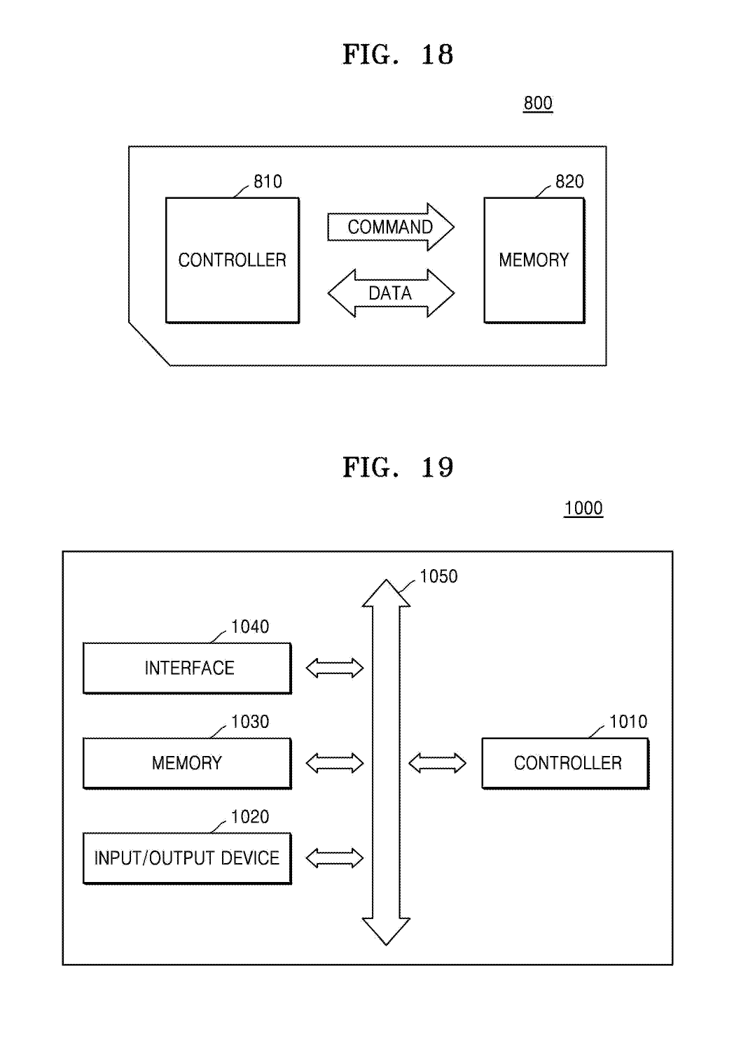

FIG. 18 is a schematic block diagram of a card 800 according to an embodiment of the inventive concept.

Specifically, in the card 800, a controller 810 and a memory 820 may be arranged to exchange electrical signals therebetween. For example, when the controller 810 transmits an instruction, the memory 820 may transmit data. The controller 820 and/or the memory 820 may include a semiconductor device according to any one of the embodiments described herein.

The memory card 800 may be any one of various types of cards, e.g., a memory stick card, a smart media (SM) card, a secure digital (SD) card, a mini SD card, and a multi-media card (MMC).

FIG. 19 is a schematic block diagram of an electronic system 1000 according to an embodiment of the inventive concept.

Specifically, the electronic system 1000 may include a controller 1010, an input/output device 1020, a memory 1030, and an interface 1040. The electronic system 1000 may be a mobile system or a system for transmitting or receiving information. The mobile system may be a personal digital assistant (PDA), a portable computer, a web tablet, a wireless phone, a mobile phone, a digital music player, or a memory card.

The controller 1010 may function to execute a program and to control the electronic system 1000. The controller 1010 may include a semiconductor device according to any one of the embodiments of the inventive concept. The controller 1010 may be, for example, a microprocessor, a digital signal processor, a microcontroller, or a similar device.

The input/output device 1020 may be used to input or output data to or from the electronic system 1000. The electronic system 1000 may exchange data with an external device, e.g., a personal computer (PC) or a network, by connecting to the external device through the input/output device 1020. The input/output device 10200 may be, for example, a keypad, a keyboard, or a display.

The memory 1030 may store codes and/or data for an operation of the controller 1010 and/or store data processed by the controller 1010. The interface 1040 may be a data transmission path between the electronic system 1000 and an external device. The controller 1010, the input/output device 1020, the memory 1030, and the interface 1040 may communicate with each other via a bus 1050. One or more of the controller 1010, the input/output device 1020, the memory 1030, and the interface 1040 may comprise a semiconductor device including one or more of the embodiments previously described herein.

For example, the electronic system 1000 may be used in mobile phones, MP3 players, navigation machines, portable multimedia players (PMPs), solid state disks (SSDs), and household appliances.

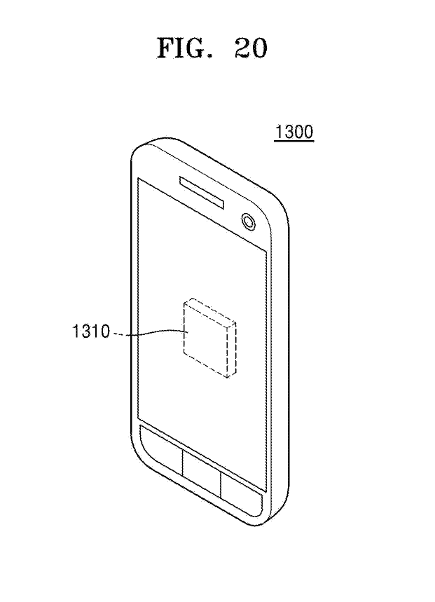

FIG. 20 is a perspective view of an electronic apparatus 1300 according to an embodiment of the inventive concept.

Specifically, FIG. 20 shows an example in which the electronic system 1000 is applied to a mobile phone 1300. The mobile phone 1300 may include a system on chip (SOC) 1310. The SOC 1310 may include a semiconductor device according to any one of the embodiments of the inventive concept described herein. The mobile phone 1300 may include the SOC in which a relatively high performance main function block may be arranged, and thus may have relatively high performance characteristics.

In addition, since the SOC 1310 may have relatively high performance characteristics while having the same area, the size of the mobile phone 1300 may be minimized and the performance of the mobile phone 1300 may be improved.

While the inventive concept has been particularly shown and described with reference to exemplary embodiments thereof, it will be understood that various changes in form and details may be made therein without departing from the spirit and scope of the following claims.

What is claimed is:

1. A semiconductor device comprising:
a substrate;
a fin structure protruding from an upper surface of the substrate including a channel region and first and second source/drain regions formed on either side of the channel region and a gate dielectric layer disposed on the channel area; and
a gate line disposed on the gate dielectric layer,
wherein the fin structure comprises:
an anti-punch through layer;
an upper fin structure disposed on the anti-punch through layer, the upper fin structure comprising a material having a lattice constant that is higher than that of silicon; and
a lower fin structure disposed under the anti-punch through layer, the lower fin structure comprising a same material as the substrate.

2. The semiconductor device of claim 1, wherein the anti-punch through layer has a dopant concentration that is higher than that of the upper fin structure.

3. The semiconductor device of claim 1, wherein the anti-punch through layer comprises at least one of a silicon layer and a silicon germanium layer.

4. The semiconductor device of claim 1, wherein the anti-punch through layer comprises an epitaxial growth layer.

5. The semiconductor device of claim 1, wherein a thickness of the anti-punch through layer is smaller than that of the upper fin structure.

6. The semiconductor device of claim 1, wherein the anti-punch through layer comprises at least two layers formed of different materials from each other.

7. The semiconductor device of claim 1, wherein the first and second source/drain regions comprise dopants of a first type and the channel region comprises dopants of a second type different from the first type.

8. The semiconductor device of claim 1, wherein the first and second source/drain regions are doped with p-type dopants.

9. The semiconductor device of claim 1, wherein the upper fin structure comprises a silicon germanium epitaxial growth layer.

10. The semiconductor device of claim 1, wherein the first and second source/drain regions each have an upper surface having a height greater than a height of an upper surface of the channel region.

11. A semiconductor device comprising:
a substrate;
a first fin structure formed in an n-type transistor area of the substrate;
a second fin structure formed in a p-type transistor area of the substrate;
a gate dielectric layer disposed on the first and second fin structures; and
a gate line disposed on the gate dielectric layer,
wherein the second fin structure comprises:
an anti-punch through layer;
a second upper fin structure disposed on the anti-punch through layer, the second upper fin structure comprising a material having a lattice constant that is higher than that of silicon; and
a second lower fin structure disposed under the anti-punch through layer, the second lower fin structure comprising a same material as the substrate.

12. The semiconductor device of claim 11, wherein the first fin structure consists of the same material as the substrate.

13. The semiconductor device of claim 11, wherein the second upper fin structure comprises a silicon germanium epitaxial growth layer.

14. The semiconductor device of claim 11, wherein the gate line extends over both the n-type transistor area and the p-type transistor area.

15. The semiconductor device of claim 11, wherein the anti-punch through layer has a doping concentration that is higher than that of the second upper fin structure.

16. A semiconductor device comprising:
a semiconductor substrate provided with a fin including a lower portion, a middle portion with a dopant of a first type and an upper portion with the dopant of the first type; and
a gate structure on sidewalls and a top surface of the fin;
wherein the middle portion comprises a first epitaxial crystalline material on the lower portion, and the upper portion comprises a second epitaxial crystalline material on the middle portion;
wherein the first epitaxial crystalline material of the middle portion comprises a first dopant with a doping concentration of x, x being a value higher than 0, and the second epitaxial crystalline material comprises a second dopant with a doping concentration of y, y being a value equal to zero or higher, where x>y; and
wherein the gate structure comprises a gate dielectric and a conductive gate line.

17. The semiconductor device of claim 16, wherein a lattice constant of the first epitaxial crystalline material is smaller than a lattice constant of the second epitaxial crystalline material.

18. The semiconductor device of claim 17, wherein the first epitaxial crystalline material is SiGe and the second epitaxial crystalline material is SiGe.

19. The semiconductor device of claim 16, further comprising:
first and second source/drain epitaxial regions formed on opposite sides of the gate structure, respectively.

20. The semiconductor device of claim 19, wherein the first and second source/drain epitaxial regions comprise a third epitaxial crystalline material having a lattice constant smaller than a lattice constant of the second epitaxial crystalline material.
